(19) United States
(12) Patent Application Publication
(10) Pub. No.: US 2019/0336879 A1
(43) Pub. Date: Nov. 7, 2019

(54) SYSTEM WITH DYNAMIC FEATURES

(71) Applicant: Canal Toys USA, Ltd., Westborough, MA (US)

(72) Inventor: Latham Gaines, Trussville, AL (US)

(73) Assignee: Canal Toys USA, Ltd., Westborough, MA (US)

(21) Appl. No.: 15/969,393

(22) Filed: May 2, 2018

(51) Int. Cl. A63H 33/00; H05K 5/02; H05K 5/00; A63H 3/00; A63H 3/16; A63H 3/28; A63H 33/04; H04R 1/02

(52) U.S. Cl. CPC A63H 33/001; H05K 5/0247; H05K 5/0086; H05K 5/0256; H04R 1/028; A63H 3/16; A63H 3/28; A63H 33/042; A63H 3/006

(57) ABSTRACT

A modeling clay system with dynamic features. The dynamic features may include: moving, waving, and/or rotating appendages (e.g. arms or antennae), illuminated eyes, and a speaking module, and other types of movable, illuminating or sound playing items. The various dynamic features may be achieved through use of electronic modules configured to provide the desired function, that is, the electronic modules may be configured to perform one or more of move, illuminate, or provide audio. The modeling clay may be electrically conductive. During use, the electronic module may be inserted into the modeling clay such that the feature is powered and exhibits the respective function.

### TECHNICAL FIELD

The present disclosure relates to a system including modeling clay and dynamic accessories configured to perform a function when coupled to the modeling clay.

### BACKGROUND

Modeling clay or clay dough is a formable and moldable material for building, creating, designing, and/or playing. Modeling clay comes in many colors and may have many accessories for forming the modeling clay and/or for adhering to the modeling clay. Accessories for forming the modeling clay may include extruders, molds, stamps, rollers, and scissors. Accessories for adhering to the modeling clay may include, appendages (e.g. arms, legs, tails, antennae, ears, etc.), shoes, hats, clothing, earrings, eyes, a mouth, etc. However, even with all of these accessories, modeling clay remains static, with no motion capabilities, except movement provided by the user. Thus, a need exists for dynamic features and systems of modeling clay that result in audio, visual, motion, etc.

### BRIEF SUMMARY

According to an embodiment, a modeling clay system may include a modeling clay formed of a conductive material; an electronic module, the electronic module including: a body having a connection point at a distal end; a pair of electrodes coupled to a power source; and a feature configured to couple to the connection point, wherein a circuit is completed when the pair of electrodes are connected to the modeling clay causing the electronic module to exhibit a dynamic function.

According to an embodiment, a method for providing a dynamic function to a feature of a modeling clay system may include coupling a feature to an electronic module; powering the electronic module by coupling a pair of electrodes on the electronic module to a modeling clay; and performing the dynamic function with the feature.

According to an embodiment, a kit for dynamic features may include one or more electronic modules, the electronic modules including one of a motor, a light, or a speaker; and one or more features, the one or more features configured to be coupled to the one or more electronic modules.

Additional features, advantages, and embodiments of the invention are set forth or apparent from consideration of the following detailed description, drawings and claims. Moreover, it is to be understood that both the foregoing summary of the invention and the following detailed description are exemplary and intended to provide further explanation without limiting the scope of the invention as claimed.

### BRIEF DESCRIPTION OF THE DRAWINGS

FIG. 1 shows a schematic of a modeling clay system having dynamic accessories, according to an embodiment of the disclosure;

FIG. 2A shows a schematic of a dynamic accessory, according to an embodiment of the disclosure;

FIG. 2B shows an exploded view of a dynamic accessory, according to an embodiment of the disclosure;

FIG. 3A shows a bottom view of an electronic module for a dynamic accessory, according to an embodiment of the disclosure;

FIG. 3B shows a front view of the electronic module of FIG. 3A, according to an embodiment of the disclosure;

FIG. 3C shows a rear half of the electronic module of FIG. 3A, according to an embodiment of the disclosure;

FIG. 3D shows a front half of the electronic module of FIG. 3A, according to an embodiment of the disclosure;

FIG. 4A shows a top view of an electronic module for a dynamic accessory, according to an embodiment of the disclosure;

FIG. 4B shows a bottom view of the electronic module of FIG. 4A, according to an embodiment of the disclosure;

FIG. 4C shows a front view of the electronic module of FIG. 4A, according to an embodiment of the disclosure;

FIG. 4D shows a rear half of the electronic module of FIG. 4A, according to an embodiment of the disclosure;

FIG. 4E shows a front half of the electronic module of FIG. 4A, according to an embodiment of the disclosure;

FIG. 5A shows a top view of an electronic module for a dynamic accessory, according to an embodiment of the disclosure;

FIG. 5B shows a bottom view of the electronic module of FIG. 5A, according to an embodiment of the disclosure;

FIG. 5C shows a front view of the electronic module of FIG. 5A, according to an embodiment of the disclosure;

FIG. 5D shows a rear half of the electronic module of FIG. 5A, according to an embodiment of the disclosure;

FIG. 5E shows a front half of the electronic module of FIG. 5A, according to an embodiment of the disclosure;

FIG. 6 shows a schematic of a circuit of a modeling clay system having dynamic accessories, according to an embodiment of the disclosure; and

FIG. 7 shows a block diagram of a modeling clay system having dynamic accessories, according to an embodiment of the disclosure.

### DETAILED DESCRIPTION

Accordingly, one embodiment includes a modeling clay system with dynamic features. The dynamic features may include: moving, waving, and/or rotating appendages (e.g. arms or antennae), illuminated eyes, and a speaking module, and other types of movable, illuminating or sound playing items. The various dynamic features may be achieved through use of electronic modules configured to provide the desired function, that is, the electronic modules may be configured to perform one or more of move, illuminate, or provide audio. The modeling clay may be electrically conductive. During use, the electronic module may be inserted into the modeling clay such that the feature is powered and exhibits the respective function. Accordingly, an interactive and dynamic modeling clay system is provided.

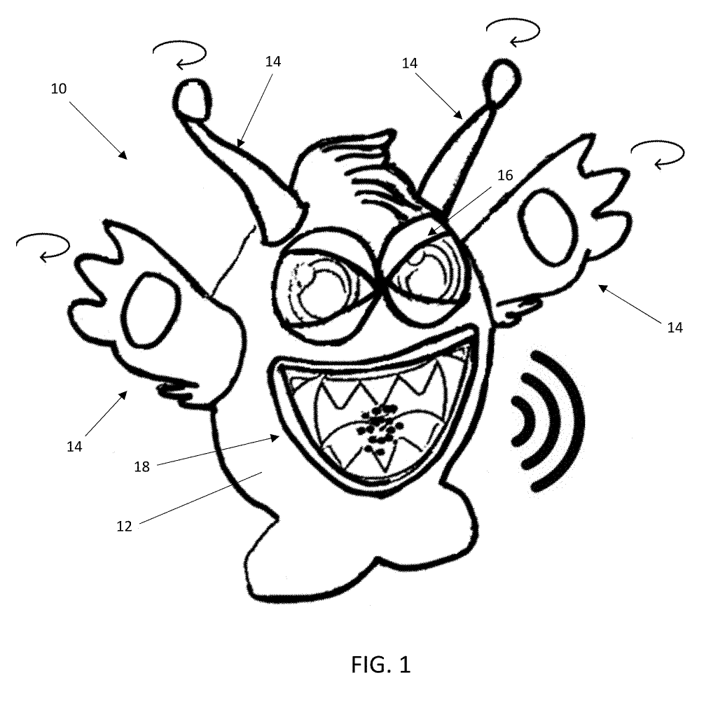

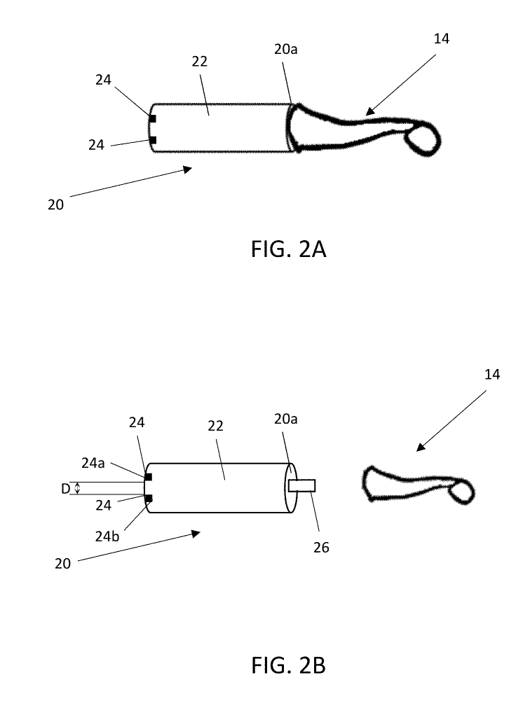

Referring to FIG. 1, a schematic of a creature 10 is shown. The creature 10 may be formed of modeling clay, clay dough, or other moldable, pliable dough-like material 12. Of course, other things may be made or formed with the clay. The creature 10 may be formed of a material, such as the modeling clay 12, that is electrically conductive. The modeling clay 12 may be any moldable substance, modeling clay, or clay dough having electrically conductive properties. The creature 10 may include first feature(s) 14, second feature(s) 16, and/or third feature(s) 18. The first feature(s) 14, second feature(s) 16, and/or third feature(s) 18 may be one or more of appendages, arms, legs, tails, antennae, ears, hair, hats, eyes, mouths, etc. The first feature 14 may be a feature configured to rotate, turn, vibrate, or otherwise move when coupled to the modeling clay 12 by an electronic module 20 (FIG. 2A). The second feature 16 may be a feature configured to illuminate, brighten, flash, or otherwise provide a visual cue when coupled to the modeling clay 12 by an electronic module 20 (FIG. 2A). The third feature 18 may be a feature configured to provide an audio output when coupled to the modeling clay 12 by an electronic module 20 (FIG. 2A).

Although a plurality of first features 14, a plurality of second features 16, and a third feature 18 are depicted, it may be appreciated that any number of first features 14, second features 16, and/or third features 18 may be provided. That is, a user may decide which of the features 14, 16, 18 and how many of the selected features may be applied to the creature 10. Any of the features 14, 16, 18 may be omitted.

Referring to FIGS. 2A and 2B, each of the features 14, 16, 18 selected to be coupled to the creature 10 may be coupled, individually or collectively, to an electronic module 20. In some cases, the feature and electronic module 20 may be integrally formed. The electronic module 20 may have a body 22. The body 22 may be generally cylindrical as shown, although other shapes are contemplated. The electronic module 20 may include one or more power sources (e.g. a battery or batteries, photovoltaic cell(s), etc.) located within or on the body 22. The power source(s) may be replaceable or rechargeable. The electronic module 20 may include a pair of electrodes 24 located on an outer surface of the body 22. The pair of electrodes 24 may include an anode 24a and a cathode 24b. The pair of electrodes 24 may be located on the bottom surface or the cylindrical surface of the body 22. The pair of electrodes 24 may be located on any surface of the body 22 such that the electrodes 24 may touch or otherwise contact the modeling clay 12 when assembled. The pair of electrodes 24 may be separated such that a circuit is not completed until the modeling clay 12 connects the pair of electrodes 24. That is, when the body 22 (comprising the electrodes 24) of the electronic module 20 is inserted or touches the modeling clay 12.

With continued reference to FIGS. 2A and 2B, the electronic module 20 may include a first end 20a having a connection point 26 for coupling to a feature 14. The first end 20a may be a distal end of the body 22. The first end 20a may include an interface, such as connection point 26, configured to translate motion to the feature 14. For example, the connection point 26 may be a shaft configured to insert into an aperture (not shown) in a lower surface of the feature 14. The connection point 26 may translate motion to the feature 14 from the electronic module 20. When coupled, the electronic module 20 may allow for the feature 14 to rotate, translate, or otherwise move.

As may be appreciated from FIGS. 2A and 2B, the electronic module 20 is shown coupled to the feature 14. The feature 14 may be configured to turn, rotate, translate, or otherwise move. Accordingly, the electronic module 20 may be provided with a motor or other motive device to provide motion to the feature 14. Alternatively, the electronic module 20 may include an LED, light, or lamp, to provide illumination to the feature 16. The electronic module 20 may include a connection point for coupling the feature 16 around the LED, light, or lamp to allow light to pass through the feature 16. Alternatively, the electronic module 20 may include an audio module and a speaker to provide sound to the feature 18. The electronic module 20 may include a connection point for coupling the feature 18 around the speaker to allow audio to pass through the feature 18. The feature 18 may include apertures or holes to facilitate the passage of the audio signal.

Additionally, with reference to FIG. 2B, the connection point 26 may take a variety of shapes. For example, where the feature is a feature 14 configured to move, the connection point 26 may couple the electronic module 20 to the feature 14 to transfer motion. For example, where the feature is a feature 16 configured to illuminate, the connection point 26 may include the light and/or may couple the electronic module 20 to the feature 16 to project light through a surface of the feature 16. For example, where the feature is a feature 18 configured to provide sound, the connection point 26 may include a speaker and/or may couple the electronic module 20 to the feature 18 to project sound through a surface of the feature 18.

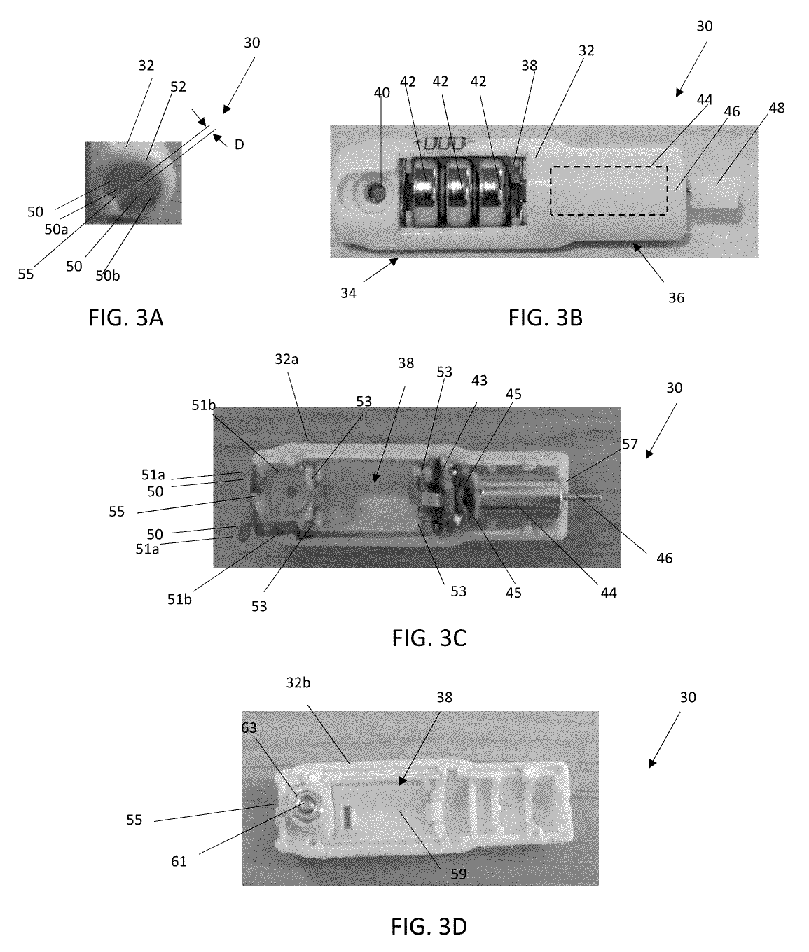

Exemplary electronic modules 20 may be seen in FIGS. 3A-3D, 4A-4E, and 5A-5D. For example, in FIGS. 3A and 3B, electronic module 30 for coupling to the feature 14 is shown. The feature 14 may be a rotating or moving feature as previously described. The electronic module may include a body 32. The body 32 may be substantially cylindrical and may include a first portion 34 configured to extend into or couple with the modeling clay and a second portion 36 configured to couple to the feature 14. The body 32 may include a compartment 38. The compartment 38 may include a cover 59 (FIG. 3D) for closing a portion of the compartment 38. The cover 59 may be secured to the body 32 with a fastener 61 secured in a nut 63 extending into a hole 40. The body 32 may include a pair of electrodes 50 located on a lower surface 52 of the body 32. The pair of electrodes 50 may include an anode 50a and a cathode 50b.

The electronic module 30 may include one or more power sources 42 located within the compartment 38. The power sources may be batteries. Although three power sources 42 are depicted, more or fewer may be provided. The one or more power sources 42 may be coupled to a motor 44 located within the compartment 38. The motor 44 may be coupled to a shaft 46 having a transmission member 48. The transmission member 48 may have a profile complementary to an inner profile of the feature 14. The transmission member 48 may be rectangular, circular, polygonal, etc. in cross-section. The feature 14 may be secured to the transmission member 48. For example, the feature 14 may have an opening in a lower surface and the transmission member 48 may be secured therein.

Referring to FIGS. 3C and 3D, an interior of the electronic module 30 is shown. The body 32 of the electronic module 30 may have a rear half 32a and a front half 32b. When coupled together, the rear half 32a and the front half 32b may define the compartment 38. The compartment 38 may house the pair of electrodes 50, the one or more power sources 42 (omitted from FIGS. 3C and 3D for clarity), an integrated circuit 43, the motor 44, wiring 45, and the shaft 46 (the transmission member 48 omitted in FIG. 3C). The shaft 46 may extend through an opening 57 in the rear half 32a and front half 32b. The pair of electrodes 50 may include the anode 50a and the cathode 50b. Each of the anode 50a and the cathode 50b may include a semi-circular portion 51a and a longitudinally extending portion 51b. The semi-circular portion 51a may be for coupling to or contacting the modeling clay. The longitudinally extending portion 51b may be for coupling the semi-circular portion 51a (and thus the modeling clay) to the one or more power sources via connections 53 and to the integrated circuit 43. The wiring 45 may couple the integrated circuit 43 to the motor 44.

The pair of electrodes 50 may be separated by a ridge 55. The ridge 55 prevents the motor 44 from activating when the pair of electrodes 50 are not coupled to the modeling clay. In operation, the modeling clay (or other conductive material) may connect the two electrodes 50, thus completing a circuit. With the circuit complete, the one or more power sources 42 may power the motor 44 to rotate. The motor 44 in turn may rotate the shaft 46 coupled to the transmission member 48. The feature 14 coupled to the transmission member 48 may rotate with the transmission member 48.

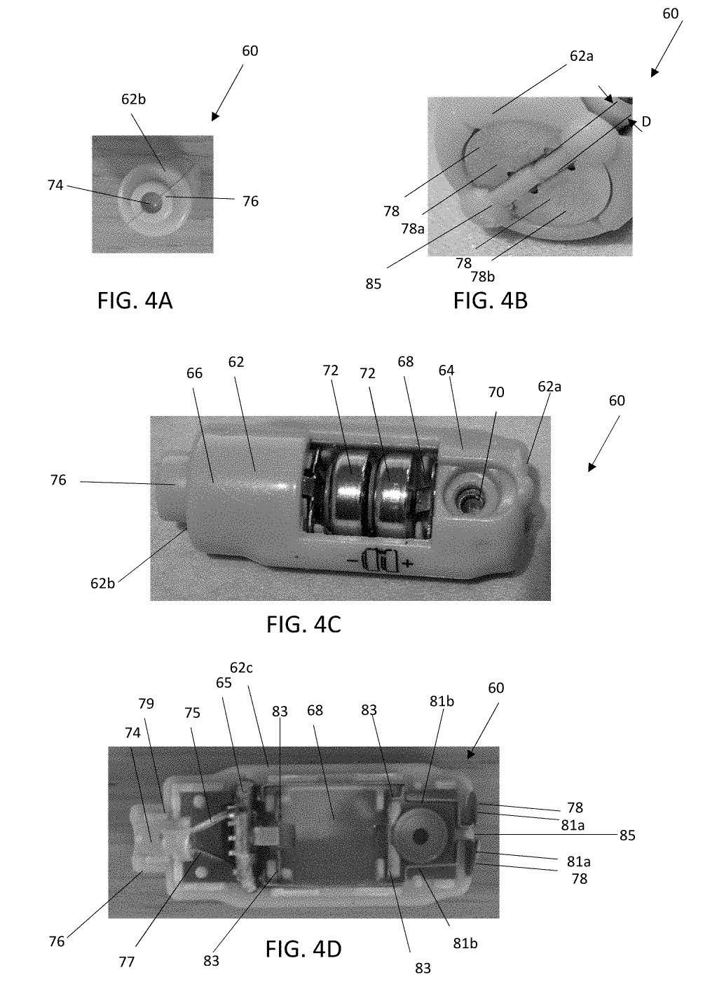

In FIGS. 4A-4E, for example, electronic module 60 for coupling to the feature 16 is shown. The feature 16 may be an illuminated feature as previously described. The electronic module may include a body 62. The body 62 may be substantially cylindrical and may include a first portion 64 configured to extend into or couple with the modeling clay and a second portion 66 configured to couple to the feature 16. The body 62 may have a lower surface 62a at a lower end of the first portion 64 and an upper surface 62b at an upper end of the second portion 66. The body 62 may include a compartment 68. The compartment 68 may include a cover 71 for closing the compartment 68. The cover 71 may be secured to the body 62 with a fastener 67 and a nut 69 extending into a hole 70. The body 62 may include a pair of electrodes 78 located on the lower surface 62a of the body 62. The pair of electrodes 78 may include an anode 78a and a cathode 78b.

The electronic module 60 may include one or more power sources 72 located within the compartment 68. The power sources may be batteries. Although two power sources 72 are depicted, more or fewer may be provided. The one or more power sources 72 may be coupled to a light 74 located within an interior of the body 62. The light 74 may be an LED. The light 74 may be included in a protrusion 76 extending from the upper surface 62b of the body 62. The feature 16 may be secured to the protrusion 76. For example, the feature 16 may have an opening in a lower surface and the protrusion 76 may be secured therein.

Referring to FIGS. 4D and 4E, an interior of the electronic module 60 is shown. The body 62 of the electronic module 60 may have a rear half 62c and a front half 62d. When coupled together, the rear half 62c and the front half 62d may define the compartment 68. The compartment 68 may house the pair of electrodes 78, the one or more power sources 72 (omitted from FIGS. 4D and 4E for clarity), an integrated circuit 65, the light 74, a light anode 75, and a light cathode 77. The light 74 may extending through an opening 79 of the protrusion 76. The pair of electrodes 78 may include the anode 78a and the cathode 78b. Each of the anode 78a and the cathode 78b may include a semi-circular portion 81a and a longitudinally extending portion 81b. The semi-circular portion 81a may be for coupling to or contacting the modeling clay. The longitudinally extending portion 81b may be for coupling the semi-circular portion 81a (and thus the modeling clay) to the one or more power sources 72 via connections 83 and to the integrated circuit 65. The light anode 75 and the light cathode 77 may couple the light 74 to the integrated circuit 65.

The pair of electrodes 78 may be separated by a ridge 85. The ridge 85 prevents the light 74 from activating when the pair of electrodes 78 are not coupled to the modeling clay. In operation, the modeling clay may connect the two electrodes 78, thus completing a circuit. With the circuit complete, the one or more power sources 72 may power the light 74 to illuminate. The light 74 may shine through the feature 16 causing the feature 16 to illuminate.

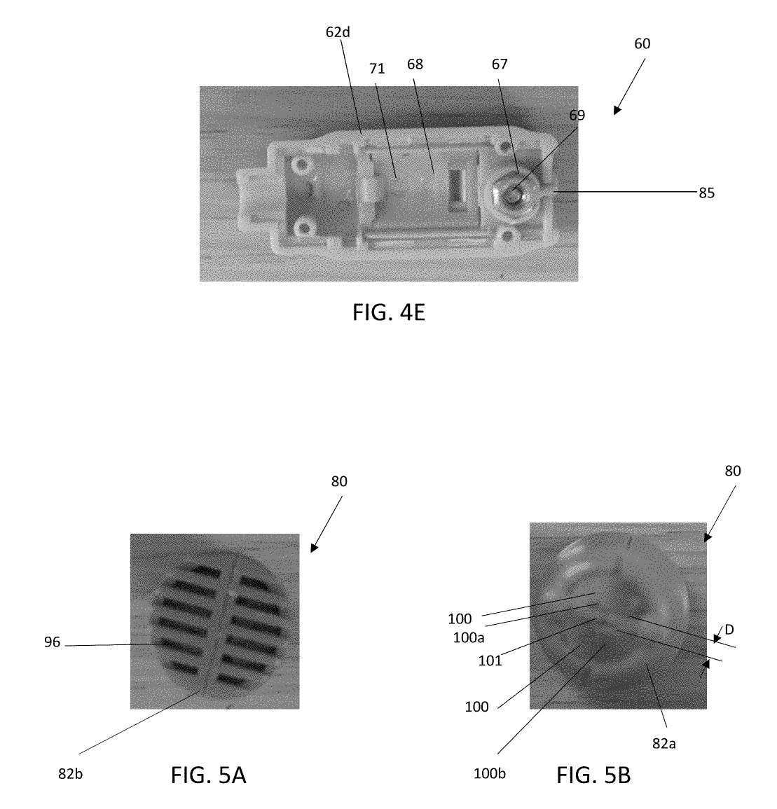

In FIGS. 5A-5E, for example, electronic module 80 for coupling to the feature 18 is shown. The feature 18 may be an audio feature as previously described. The electronic module may include a body 82. The body 82 may be substantially cylindrical and may include a first portion 84 configured to extend into or couple with the modeling clay and a second portion 86 configured to couple to the feature 18. The body 82 may have a lower surface 82a at a lower end of the first portion 84 and an upper surface 82b at an upper end of the second portion 86. The body 82 may include a compartment 88. The compartment may include a cover 87 for closing the compartment 88. The cover may be secured to the body 82 with a fastener 89 and nut 91 extending into a hole 90. The body 82 may include a pair of electrodes 100 located on the lower surface 82a of the body 82. The pair of electrodes 100 may include an anode 100a and a cathode 100b.

The electronic module 80 may include one or more power sources 92 located within the compartment 88. The power sources may be batteries. Although three power sources 92 are depicted, more or fewer may be provided. The one or more power sources 92 may be coupled to an outwardly tapered portion 94. The outwardly tapered portion 94 extend to the upper surface 82b. The upper surface 82b may comprise a plurality of longitudinal openings 96. The one or more power sources 92 may be coupled to a speaker 98 located within an interior of the body 82. The speaker 98 may be included in the outwardly tapered portion 94. The feature 18 may be secured to the upper surface 82b. For example, the feature 18 may have an opening in a lower surface and the upper surface 82b may be secured therein.

Referring to FIGS. 5D and 5E, an interior of the electronic module 80 is shown. The body 82 of the electronic module 80 may have a rear half 82c and a front half 82d. When coupled together, the rear half 82c and the front half 82d may define the compartment 88. The compartment 88 may house the pair of electrodes 100, the one or more power sources 92 (omitted from FIGS. 5D and 5E for clarity), an integrated circuit 93, the speaker 98, and wiring 95. The speaker may be located in the outwardly tapered portion 94. The pair of electrodes 100 may include the anode 100a and the cathode 100b. Each of the anode 100a and the cathode 100b may include a semi-circular portion 97a and a longitudinally extending portion 97b. The semi-circular portion 97a may be for coupling to or contacting the modeling clay. The longitudinally extending portion 97b may be for coupling the semi-circular portion 97a (and thus the modeling clay) to the one or more power sources 92 via connections 99 and to the integrated circuit 93. The wiring 95 may couple the speaker 98 to the integrated circuit 93.

The pair of electrodes 100 may be separated by a ridge 101. The ridge 101 prevents the speaker 98 from activating when the pair of electrodes 100 are not coupled to the modeling clay. In operation, the modeling clay may connect the two electrodes 100, thus completing a circuit. With the circuit complete, the one or more power sources 92 may power the speaker 98 to produce a prerecorded audio stream. The speaker 98 may produce sound which extends through the upper surface 82b via the plurality of longitudinal openings 96 and through openings on the feature 18.

Accordingly, it may be appreciated that one or more electronic modules 20, 30, 60, and 80 may be provided. The one or more electronic modules 20, 30, 60, and 80 may include motive devices (e.g. motor 44), lights (e.g. light 74), or speakers (e.g. speaker 98) within the one or more bodies of the electronic modules 20, 30, 60, and 80. The one or more electronic modules 20 may include one or more connection points configured to connect to the particular feature 14, 16, or 18. This allows the features 14, 16, 18 to be interchangeable with the modules 20, 30, 60, and 80.

Referring to FIGS. 3A-3D, 4A-4E, and 5A-5E, it may be understood that each of the pair of electrodes 24, 50, 78, and 100 may include an anode and cathode. The anode and cathode may be separated from each other by a strip or ridge of non-conductive material, such as plastic. The non-conductive material between the anode and cathode may prevent the motor, light, and/or speaker from operating until activated by the modeling clay. The anode and cathode may be located in close proximity to one another. For example, the innermost surface of each of the anode and cathode may be located a distance D of about 0.0625 inches (1.5875 mm). The anode and cathode may each be constructed as a semi-circles such that the fit within the profile of the generally tubular body of the electronic modules 20, 30, 60, and 80. The anode and cathode may be substantially identical. The anode and cathode may be formed of a material that is resistant to corroding. The anode and the cathode may be formed of the same material.

For example, referring back to FIG. 1, each of the features 14 (e.g. the two antennae and the two arms) may be coupled with electronic modules 30 including batteries and motive devices (e.g. motors) for rotating, translating, or otherwise moving the feature 14. The feature 16 (e.g. the eyes) may be provided with an electronic module 60 including batteries and a lamp or LED for illuminating the feature 16. The feature 18 (e.g. the mouth) may be provided with an electronic module 80 including batteries and a speaker for providing an audio sound through the feature 18. Thus, when assembled, the creature 10 may have appendages which rotate or move (e.g. features 14), eyes which light up (e.g. feature 16), and a mouth which talks, growls, or provides other expressions (e.g. feature 18).

During use, a user, such as a child, may form a shape, such as a creature 10, with the modeling clay 12. The forming may be performed free-hand or with a mold. The creature 10 may be a monster, alien, animal, person, fish, etc. Once the creature 10 has been formed, the child may select the desired features to be added to the creature 10. The features may be selected from the group of features 14, 16, 18 previously described. The child may couple the features 14, 16, 18 to the appropriate electronic modules 20, 30, 60, and 80. That is, the features 14 which the child desires to move may be coupled to electronic modules 30 which include motive devices, the feature 16 which the child desires to illuminate may be coupled to electronic modules 60 which include a lamp or LED, and/or the features 18 which the child desires to talk may be coupled to electronic modules 80 which include speakers.

The child may insert the electronic module 20 (for ease of reference, electronic module 20 is referred to herein, however it is understood the electronic module 20 may be any of electronic modules 30, 60, or 80) into the modeling clay 12 of the creature 10. The electronic module 20 may be inserted partially into the modeling clay 12 or wholly into the modeling clay 12 such that no portion of the electronic module 20 is visible. The child may insert the electronic module 20 into the modeling clay 12 such that the electrodes 24 (FIG. 2) on the electronic module 20 are in contact with the modeling clay 12. Since the modeling clay 12 is an electrically conductive material, a circuit will be completed once assembled. The connection between the electrically conductive material of the modeling clay 12 and the electronic module 20 powers the component (e.g. the motor, the light, and/or the speaker) within the body 22 of the electronic module 20. Thus, once inserted into the modeling clay 12, the electronic module 20 may actuate the motor for moving or rotating the feature 14, turn on the light for illuminating the feature 16, and/or actuate the speaker for causing the feature 18 to speak. The dynamic action (e.g. motion, illumination, or audio) provided by the features 14, 16, and 18 may be programmed to operate for a predetermined period of time and/or may include a cutoff circuit. The features 14, 16, and 18 may be programmed to automatically shut-off or end at the end of the predetermined period of time. Alternatively, the cutoff circuit may activate after the predetermined period of time. For example, the features 14, 16, and 18 may operate for 20 seconds and then the cutoff circuit may activate and the dynamic action may end. The cutoff circuit may be an integrated circuit including in the compartment or interior of the body of the electronic module 20. In this manner, the features 14, 16, and 18 may automatically shut off.

Alternatively, the child may place any desired number of features 14, 16, 18 on the creature 10 without the electronic module 20 such that the features 14, 16, 18 extend from the creature 10 without performing a dynamic function (e.g. moving, illuminating, or audio) and appear as static features. In this manner, the child may assemble a creature 10 which has partial static features and partial dynamic features. Alternatively, the child may assemble a creature 10 with only static features or only dynamic features. As may be appreciated, the child may select any number of combinations of static and/or dynamic features, the dynamic features being any number of combinations of moving, illuminating, or speaking features.

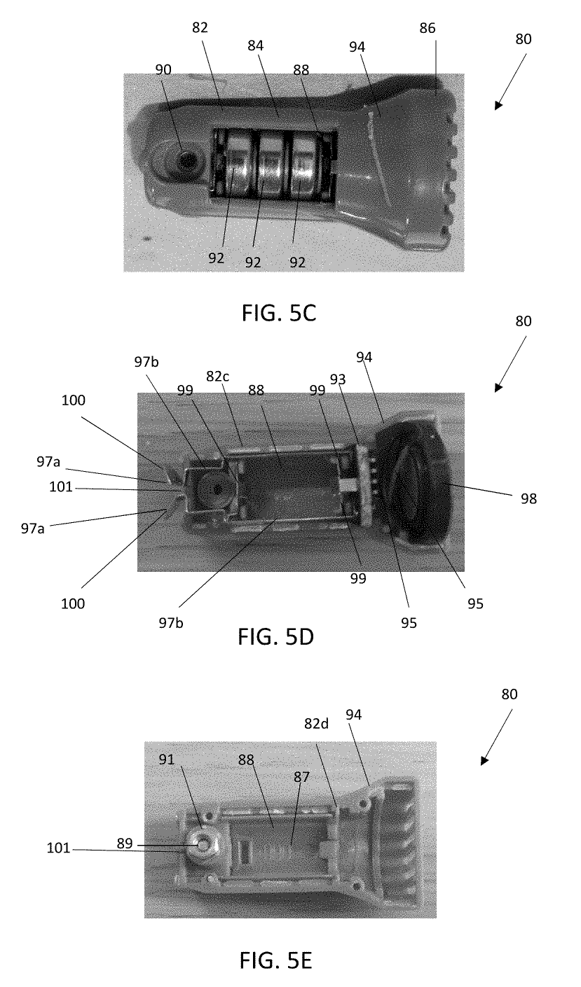

Referring to FIG. 6, a schematic electric circuit of the modeling clay system is depicted. As previously described, the system may be provided with an electronic module 20 having within, on a surface of, or coupled thereto, a power source 28 and electrodes 24. Alternatively the power source 28 and electrodes 24 need not be provided with the electronic module 20 and may be provided as individual components. The electrodes 24 may be connected to the power source 28 which is turn connected to the motive device, light or LED, and/or sound module. These connections may be formed such that they are always in electrical connection. However, the circuit may not be complete until the electrodes 24 come in contact with, through one of the aforementioned manners, the modeling clay 12. Thus, the modeling clay 12 may complete the circuit, the completed circuit powering the motive device, light or LED, and/or sound module.

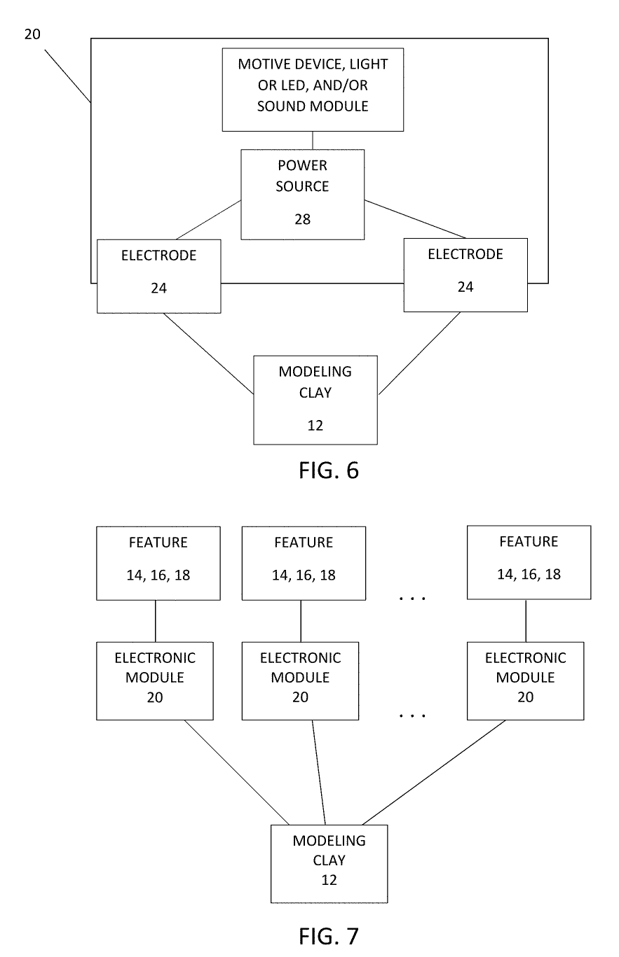

Referring to FIG. 7, a block diagram of the modeling clay system is depicted. As may be appreciated from the foregoing disclosure, the features 14, 16, 18 may include a connection point for coupling to their respective electronic module 20. The electronic module 20 in turn is connected to the modeling clay 12 by pressing or pushing or otherwise inserting the electronic module into the soft or pliable modeling clay 12. Due to the conductive properties of the modeling clay 12, once the connection is provided between the electronic module 20 and the modeling clay 12, the desired dynamic capability of the feature is exhibited by way of the electronic module 20. It may be appreciated that, in some embodiments, prior to connecting to the modeling clay 12, the feature connected to the electronic module 20 does not perform a dynamic function since the circuit has not yet been completed. Accordingly, it is preferable the features do not move, illuminate, or speak until their respective electronic modules 20 are inserted into, touching, or otherwise connected to the modeling clay 12.

Although only a single feature 14, 16, 18 is depicted coupled to a single electronic module 20, it may be appreciated that other numbers of connections may be provided. For example, an electronic module 20 may be provided with two connection points, one for motion and one for illumination, or both for motion, or both for illumination, or any combination of functions. The electronic module 20 may be provided with one, two, three, or more connection points for coupling to features 14, 16, 18. Alternatively, each of the electrodes 24 of the pair of electrodes may be provided in separate electronic modules 20. The separate electronic modules 20 may in turn be coupled to one or more features 14, 16, 18 to provide the desired dynamic function. In this manner, each of the electrodes could be located on opposing sides or differing locations around the creature 10.

A kit may be provided including the parts of the modeling clay system. The kit may include one or more colors of modeling clay 12, one or more features 14, one or more features 16, one or more features 18, and one or more electronic modules 20 for the respective features 14, 16, 18 (as previously described). The kit may also include molds for forming a creature 10 and one or more tools (e.g. a knife, fork, roller, extruder, etc.) for assisting in the forming or design of the creature 10.

Only exemplary embodiments of the present invention and but a few examples of its versatility are shown and described in the present disclosure. For example, the module 20 may take any form, shape or size, such as circular, arced, polygonal, etc., be shaped like a hat, clothing, accessory, etc It is to be understood that the present invention is capable of use in various other combinations and environments and is capable of changes or modifications within the scope of the inventive concept as expressed herein.

Although the foregoing disclosure describes modeling clay, it is understood that other types of electrically conductive materials may be provided. For example, the material may be slime, dough, putty, clay, electrically conductive compounds, floam, foam, any material comprising water and/or salt, etc. Additionally, although rotating, illumination, and audio are described, other dynamic features may be provided. For example, the features may spin, vibration, shake, extend, retract, reciprocate, rattle, flap, oscillate, flicker, flash, twinkle, etc.

Although the foregoing description is directed to the preferred embodiments of the invention, it is noted that other variations and modifications will be apparent to those skilled in the art, and may be made without departing from the spirit or scope of the invention. Moreover, features described in connection with one embodiment of the invention may be used in conjunction with other embodiments, even if not explicitly stated above.

1. A modeling system, the modeling system comprising:
a conductive material;
an electronic module, the electronic module including:
a body having a connection point at a distal end;
a pair of electrodes coupled to a power source; and
a feature configured to couple to the connection point,
wherein a circuit is completed when the pair of electrodes are connected to the conductive material causing the electronic module to exhibit a dynamic function, and
wherein the electronic module is configured to detachably couple to the feature, the conductive material, or both.

2. The modeling system of claim 1, wherein the dynamic function is one of moving, illuminating, or speaking.

3. The modeling system of claim 1, wherein the electronic module includes a motor for providing rotary motion to the feature, and wherein, when the electronic module is connected to the conductive material, the motor rotates.

4. The modeling system of claim 1, wherein the electronic module includes a light for illuminating the feature, and wherein, when the electronic module is connected to the conductive material, the light illuminates.

5. The modeling system of claim 1, wherein the electronic module includes a speaker for providing audio sounds through the feature, and wherein, when the electronic module is connected to the conductive material, the speaker actuates providing audio sounds.

6. The modeling system of claim 1, wherein the power source is one or more batteries.

7. The modeling system of claim 1, wherein the feature is one of an appendage, an arm, a leg, a tail, an antennae, an ear, a shoe, a hat, a piece of clothing, an earring, an eye, or a mouth.

8. A method for providing a dynamic function to a feature of a modeling system, the method comprising:
coupling a feature to an electronic module;
powering the electronic module by coupling a pair of electrodes on the electronic module to a conductive material; and
performing the dynamic function with the feature,
wherein the electronic module is configured to detachably couple to the feature, the conductive material, or both.

9. The method of claim 8, wherein the dynamic function is one of moving, illuminating, or speaking.

10. The method of claim 8, further comprising completing a circuit by coupling the electronic module to a modeling clay.

11. The method of claim 10, wherein the modeling clay is electrically conductive.

12. A kit for dynamic features, the kit comprising:
one or more electronic modules, the electronic modules including one of a motor, a light, or a speaker; and
one or more features, the one or more features configured to be detachably coupled to the one or more electronic modules.

13. The kit of claim 12, the one or more features further comprising one or more of an appendage, an arm, a leg, a tail, an antennae, an ear, a shoe, a hat, a piece of clothing, an earring, an eye, or a mouth.

14. The kit of claim 12, the one or more electronic modules further comprising one or more batteries.

15. The kit of claim 12, further comprising:
one or more containers of modeling clay;
a tool; and
one or more molds.

16. The modeling system of claim 1, wherein the pair of electrodes and the power source are housed by the body.

17. The modeling system of claim 16, wherein a portion of the pair of electrodes are located on an outer surface of the body, and wherein the connection point is at an opposing side of the body from the pair of electrodes.

18. The modeling system of claim 1, wherein the feature is configured to be interchangeable with another feature at the connection point.
